(19) United States
(12) Patent Application Publication
(10) Pub. No.: US 2007/0117413 A1
(43) Pub. Date: May 24, 2007

(54) Process for the production of a nitrogenous layer a semiconductor or metal surface

(76) Inventor: Zsolt Nenyei, Blaustein (DE)

Correspondence Address: DORITY & MANNING, P.A., POST OFFICE BOX 1449, GREENVILLE, SC, 29602-1449, US

(21) Appl. No.: 10/567,626

(22) PCT Filed: Aug. 26, 2004
(86) PCT No.: PCT/EP04/09512

§ 371 Date: Dec. 13, 2006

(30) Foreign Application Priority Data
Sep. 18, 2003 (DE) 103 43 692.8

(51) Int. Cl. H01L 21/31

(52) U.S. Cl. 438/791

(57) ABSTRACT

A first process for the production of a thin nitrogenous layer on a semiconductor surface by contacting at least a part of the surface with a nitrogenous liquid, by applying an electrical voltage between the surface, the liquid and an electrode according to a given voltage-time curve until a layer thickness of less than 5 nm is formed, and then separating the surface from the liquid. A second process for the production of a thin nitrogenous layer on a metal surface or on a metal layer located on a substrate by at least a part of the surface or the metal layer with a nitrogenous liquid, by applying an electrical voltage between the surface or metal layer, the liquid and an electrode according to a given voltage-time curve until a layer thickness of less than 50 nm is formed, and then separating the surface or the metal layer from the liquid. A third process for detaching an oxygen-containing and/or nitrogenous layer on a semiconductor or a metal surface.

The present invention relates to a process for the production of a thin nitrogenous or nitrogen containing layer on a semiconductor substrate, on at least a metallic coating of a coated semiconductor substrate, or on a metal.

Preferably, the metal or semiconductor surface is located on a semiconductor substrate e.g. a silicon wafer which may be unstructured, or to which structures for forming semiconductor components, or at least one metallic coating have been applied.

When manufacturing semiconductors, thin nitrogenous layers are employed, in particular, as the gate dielectric for MOSFET and CMOS transistors in order to produce components having dimensions in the sub-micrometer range, whereby here, the previously used dielectric isolation layer of silicon dioxide SiO₂, which today has a thickness of from just 1 nm to 2 nm, is replaced by nitrogenous dielectric layers such as are described in more detail by E. P. Gusev et al. (Electrochemical Society Proceedings, volume 2003-02, pages 465-475). The replacement of SiO₂ as the gate material was necessary because of a number of fundamental disadvantages inherent to this material such as e.g. the exponentially increasing leakage current through this isolation layer as the thickness of the SiO₂ layer decreases, this being essentially determined by the quantum-mechanical tunnelling effect. A further disadvantage is that the breakdown voltage of transistors having such thin SiO₂ gate layers is substantially reduced. By using silicon oxynitrides SiOₓN_{y} and silicon nitride Si₃N₄ as the gate dielectric, the aforementioned disadvantages can be overcome, or the dimensions of the components or those of the structures can be further reduced and thus the integration density of a component can be increased whilst maintaining the same level of quality. Furthermore silicon oxynitrides SiOₓN_{y} or silicon nitride Si₃N₄ exhibit a substantially better barrier effect e.g. against Bohr diffusion than a pure SiO₂ layer.

In essence, two nitriding methods are used for the production of nitrogenous layers such as silicon oxynitrides SiOₓN_{y} and silicon nitride Si₃N₄.

On the one hand, a thermal oxidation/nitridation process with partial thermal annealing, and, on the other hand, a chemical or physical deposition process such as an e.g. CVD process (Chemical Vapour Deposition) or a deposition process by means of a nitrogen plasma. In dependence on the process being used, the proportion of nitrogen in the dielectric layer amounts to between 0% and 57% (here, in the case of Si₃N₄, the percentage figures are atom per cent) whereby approximately 10¹⁴ to approximately 6×10¹⁵ N-atoms/cm² are created in a 1 nm to 2 nm thick silicon oxynitride SiOₓN_{y}.

The morphology of the nitrogenous layers depends essentially on the process being used. Thus, layers produced by a CVD process differ from those produced by means of a thermal process in that in the CVD process, a nucleation (non-coherent) process occurs first followed by a process in which the nuclei grow together (coalescence) to form a closed layer, whereas in the thermal processes, a very uniform thermal growth process results in an almost closed layer. This different manner of growing a layer is of particular importance especially in the case of very thin layers, in particular, in regard to the attainable homogeneity of the layer.

The physical thickness of a gate layer made from a generic silicon oxynitride SiOₓN_{y} or consisting of silicon nitride Si₃N₄ can be somewhat thicker than a corresponding gate layer of SiO₂ for the same capacity of components due to the higher dielectric constant. For example, the disturbing tunnelling current through the dielectric isolation layer is substantially reduced by virtue of the increased physical thickness of the layer. The layer thickness of the gate layer is often expressed in nanometres or Angstroms (1 Angstrom=10⁻¹⁰ m) EOT (Equivalent Oxide Thickness) relative to a corresponding SiO₂ layer of the same capacity. Hereby, as already mentioned, the physical thickness of the layer is then somewhat greater than the indicated nanometres or angstroms in EOT.

F. N. Cubaynes et al., (Electrochemical Society Proceedings, volume 2003-02, pages 595-604) as well as M. Bidaut et al. (Electrochemical Society Proceedings, volume 2003-02, pages 517-523) describe the production of dielectric gate layers in the sub 15 Angstrom range by means of a plasma nitridation process. Here, an Si substrate having an SiO₂ film of 0.4 nm to 1.6 nm thickness is exposed to an N₂ plasma for the purposes of nitridation, this then being followed by a thermal annealing process. The disadvantage of the plasma nitridation process is that it produces a large number of defects which are not easy to eliminate even by means of a following thermal annealing process.

A further substantial disadvantage of the previously described processes for the production of nitrogenous films or layers is that any oxygen that may be present in the layer diffuses towards the boundary surface of the bulk silicon Si and oxidizes it, i.e. forms SiOₓ (2>x>0) or SiO₂ with the silicon. There is thus developed a kind of double layer consisting of the silicon oxynitride (SiOₓN_{y}) layer or the silicon nitride (Si₃N₄) layer on the surface of the substrate and a second layer consisting essentially of SiO₂ at the boundary surface of the bulk silicon material of the semiconductor. This oxidation is referred to as parasitic re-oxidation and has a limiting effect in regard to a reduction of the EOT parameter, which counteracts any further reduction in the geometrical dimensions of the component.

Furthermore, it is difficult to eliminate any natural oxide within the structures of structured wafers.

The first object of the present invention is to provide a process which overcomes the aforementioned disadvantages in regard to the production of a nitrogenous layer on a semiconductor substrate or a semiconductor surface, and in particular, the disadvantage of the parasitic re-oxidation.

A further, second object of the present invention is to provide a new process with the aid of which at least a metal layer deposited on a semiconductor or, more generally, a metal is at least partly (or completely) nitrided or oxynitrided, in order to form a metal nitride or a metal oxynitride layer.

In accordance with the invention, the first object is achieved by a process for the production of a thin nitrogenous layer on a semiconductor surface comprising the following process steps:
contacting at least a part of the surface with a nitrogenous liquid,
applying an electrical voltage between the surface, the liquid and an electrode according to a given voltage-time curve until a layer of thickness less than 5 nm is formed, and
separating the surface from the liquid.

Due to the application of an electrical voltage between the surface (which is preferably the surface of a semiconductor substrate) and the liquid by means of an electrode which is preferably but not necessarily used as a cathode, the nitriding of the surface is effected in a transformation or conversion process, preferably an anodic conversion process, so that a nitrogenous layer is formed thereon by means of an electro-chemical process. In general and within the framework of this application, the surface can be formed on a substrate by one or more semiconductors and/or by a layer or layers comprising a metal or a plurality of metals, whereby the substrate itself may consist of a semiconductor or a metal, or a ceramic or a glass. Hereby, the ceramic and glass are then coated with the materials forming the surface in a corresponding manner. By using a suitable voltage-time curve for the applied voltage, particularly thin layers (nitride or oxynitride layers) having a thickness of less than 5 nm can advantageously be produced on a semiconductor surface, e.g. on a silicon surface, the thickness of the layers preferably being thinner than 2 nm.

In the case of metals or metal layers on a semiconductor, the thickness of the layer is preferably less than 50 nm, and for some applications less than 20 nm. If one is dealing with thin metal layers on a semiconductor (thinner than some 100 angstroms), then the entire metal layer can be nitrided or oxynitrided. The process in accordance with the invention for the production of a nitrogenous layer on a metal surface or a metal layer located on a substrate is characterised by the following process steps for the purposes of achieving the second object:
contacting at least a part of the surface or the metal layer with a nitrogenous liquid,
applying an electrical voltage between the surface or the metal layer, the liquid and an electrode according to a given voltage-time curve until a layer of thickness less than 50 nm is formed, and
separating the surface or the metal layer from the liquid.

The thicknesses of the layer in the case of a semiconductor substrate consisting of silicon are also measured in EOT i.e. layer thicknesses of less than 5 nm EOT are producible by the processes in accordance with the invention. Preferably, a layer thickness of between 0.3 nm and 1.5 nm in terms of physical thickness or EOT thickness is produced.

In dependence on the liquid, the nitrogenous liquid is generally at a temperature of less than 150° C., and is preferably at less than room temperature or below 0° C.

In the case of the first mentioned process in accordance with the invention, it is advantageous that the formation of defects is reduced e.g. in comparison with the plasma nitridation process and it is also advantageous that a very uniform self-adjusting layer is formed, this being similar to or better than one produced by the thermal processes. The improved morphology of the layer structure due to the process in accordance with the invention results essentially from the self-adjusting property that is effective in the case of electro-chemical processes, the reason for this being that the local electrical resistance generally increases and thus the local electrical field strength in the liquid reduces with increasing layer thickness, this in turn resulting in a reduction of the growth rate of the layer i.e. the speed at which the layer is formed (e.g. in the case of layer conversion processes).

Due to the aforementioned advantages, the first process is suitable for the production of e.g. ultra thin nitride layers such as are made use of for characteristic structures (such as those for e.g. the gate length of transistors or half-pitch lengths) of less than 100 nm. The uniform layer structure obtained by the process in accordance with the invention enables the manufactured layers to be employed as seed layers for an e.g. subsequent CVD or ALD (Atomic Layer Deposition) process. Moreover, the layer produced by the process in accordance with the invention can be subjected to further nitridation in a subsequent thermal process e.g. a thermal nitridation process in a process gas atmosphere containing e.g. NH₃, whereby substantially better scalable layer (interface) properties are attainable.

By adding fluorine-containing compounds to the nitrogenous liquid, the first and second processes in accordance with the invention or individual process steps from these processes in accordance with the invention can also be employed, to advantage, in a further process in accordance with the invention namely, for detaching an oxygen-containing and/or a nitrogenous layer on a semiconductor surface or a metal surface (in each case, with optional surface passivation) by using the process steps:
contacting at least a part of the surface with a water-free nitrogenous liquid, incorporating a fluorine-containing substance,
and separating the surface from the liquid.

Here, HF and NH₄F were selected as examples of a fluorine-containing substance. In processes for the detachment of an oxygen-containing layer and/or a nitrogenous layer, an electrical voltage can additionally be applied between the surface (e.g. a semiconductor substrate), the liquid and an electrode according to a given voltage-time curve, as was done in the case of the process for the production of a nitrogenous layer.

As previously mentioned, the process in accordance with the invention can be employed, in particular, for semiconductor substrates which consist essentially of silicon such as e.g. silicon wafers. Hereby, the silicon wafers may already comprise a layer on the surface thereof, e.g. an SiO₂ layer or the surface may already be structured, whereby the structures serve for the production of semiconductor components such as e.g. transistors (CMOS, MOSFET).

Liquid ammonia NH₃ is preferably used as the nitrogenous liquid, whereby the corresponding boiling point is −33.4° C. and the melting point is −77.8° C. The physical behaviour of liquid ammonia is similar to that of water in regard to many of its properties. Thus, many salts and other chemicals can be dissolved in liquid ammonia, in a similar manner to dissolving them in water, this thereby enabling it to be employed in electro-chemical processes. In particular, it is possible to produce electrolytes which, for example, advantageously affect the electrical conductivity of the liquid e.g. increase it. In addition, it is possible to affect the solubility of the anodically produced nitride or nitroxide (oxynitride) layers by the choice of the added chemicals and/or the type and magnitude of the electrical voltage between the semiconductor and the liquid (or an electrode). It is thereby possible to determine the size or the thickness of the nitride or oxynitride (nitroxide) layer by anodic conversion such as is known from the anodic treatment (e.g. oxidation) of aluminium.

As an alternative or in addition thereto, a layer such as an e.g. oxygen-containing layer e.g. an oxide coating on a silicon wafer (e.g. the natural oxide coating which is also referred to as “native oxide”) or such a layer on the component structures and which said layer is already present on the surface e.g. on the semiconductor surface and/or on the component structures can be detached in situ or reduced in thickness by the aforementioned processes. Mention is made of an example that is currently at an experimental stage wherein NH₄F is added to liquid ammonia in order to reduce or detach the oxide coatings specified above. Thus, for example, by using the first and second processes, this opens up the possibility of producing a “native” nitride or oxynitride layer, which is comparable to the “native oxide” layer, on silicon e.g. on a silicon wafer (on metals or on metal layers located on a semiconductor, e.g. a tungsten layer on silicon) by means of liquid ammonia or an electrolyte which is based on liquid ammonia. As metals or metal layers, mention is made, in particular, of aluminium, titanium, zirconium, hafnium, tantalum, tungsten or elements of other transition metals. In particular, the prospect exists that the production of such nitrogenous layers on a semiconductor or on a metal or on a metal layer including the detachment or reduction of an already existing layer such as the e.g. previously mentioned “native oxide” coating (or a nitride or oxynitride layer) can be accomplished in an electro-chemical process within a nitrogenous liquid.

As a further example of a nitrogenous liquid, mention is made of liquid hydrazine (N₂H₄), which is present in liquid form under normal conditions between 1.4° C. and 113.8° C. Electrolytes having a hydrazine base can also be developed in a manner analogous to that mentioned above for ammonia, by the addition of appropriate salts or other chemicals. The homologues of the different hydrazine hydrates (N₂H₄.H₂O, N₂H₄.2H₂O, N₂H₄.xH₂O , . . . ) including their aqueous solutions (and also aqueous ammonia solutions) can also be used as the nitrogenous liquid and form the basis for an electrolyte. When using ammonia and especially hydrazine or solutions based upon these substances, especial mention must be made of the somewhat poisonous nature and inflammability thereof. In a preferred embodiment, nitrogenous liquids are selected which are free from dissolved and/or bound oxygen and/or are free from water.

Furthermore, other, alternative substances for producing special electrolytes may comprise nitrogen, hydrogen, oxygen, fluorine and also carbon (including their isotopes). Thus carbamide (CO₂(NH₂)) melts at 132.7° C. Anodic nitroxide layers could be produced in a melt of this type.

Apart from the substances mentioned above, mixtures of these can also be used, whereby a substance in gaseous form can be dissolved in gaseous form in another substance that is present in liquid form. Moreover, the previously mentioned substances could also be dissolved in gaseous form in a liquid. Furthermore, additives such as the already mentioned e.g. NH₄F or HF could be added to the liquids in order to e.g. detach in situ or reduce the concentration or thickness of any e.g. oxide layer such as e.g. natural SiO₂ on a silicon wafer (for this purpose, use can also be made of different or additional chemicals which assist the detachment of an oxygen-containing layer). In correspondence with the patents JP140721-75 (DE 26 39 004 C2), choline (trimethyl-2 hydroxyethyl ammonium hydroxide) or its homologue can also be used as an additive.

Aqueous solutions such as an e.g. 30% ammonia solution can also be used as yet other nitrogenous liquids, whereby here however, the nitrogen content in the layer is very small.

Preferably, any oxygen-containing compound such as e.g. SiO₂ and/or SiOₓ at the surface of the semiconductor substrate is, in the case of an Si wafer, completely or at least partially removed prior to contacting the substrate surface with the nitrogenous liquid. This can be effected in known manner by means of e.g. HF in a DHF (Diluted HF) process for example, the surface then being passivated by means of hydrogen.

Alternatively, the passivating process can also be effected in a general manner by NHₓ (preferably NH₂) by means of a treatment with an e.g. nitrogenous liquid such as e.g. NH₃, N₂H₄, N₂H₄.H₂O or an NH₃—NH₄F mixture. Hereby for example, the NH₂ groups are adsorbed in the semiconductor surface whereby surface oxidation of the semiconductor is prevented to a large extent. In contrast to the process of passivating the semiconductor surface (the Si surface) with pure hydrogen which prevents oxidation of the semiconductor up to approximately 600° C., a surface can be protected from disturbing oxidation up to about 300° C., and partially up to 400° C. in the case of a surface passivating process using NHₓ. This is sufficient for most applications and, moreover, this has the advantage that fluorine is not used for passivating the surface as is the case for a passivating process using hydrogen. A fluorine-free passivating process is preferred today in many semiconductor plants. For the purposes of removing oxide coatings from the semiconductor surface and/or for passivating a surface by means of a nitrogenous liquid, an electrical voltage can be applied between the semiconductor and the liquid, although this is generally dispensed with.

It is explicitly pointed out that in the case of all the hydrogen-containing compounds that have been mentioned, the hydrogen can be replaced by its isotopes, preferably by deuterium, and that the nitrogenous liquid may incorporate hydrogen and/or at least one of its isotopes.

Preferably, after separating the surface e.g. the substrate surface from the liquid, this surface (e.g. the semiconductor substrate) is exposed to a lithographic and/or at least one thermal treatment step such as e.g. thermal growth of the nitrogenous layer in a nitrogenous environment. In the case of a thermal treatment step, this is preferably an RTP (Rapid Thermal Processing) step wherein the substrate is heated within a few seconds up to 900° C. or more in a defined gaseous atmosphere or in vacuum.

For semiconductors (e.g. silicon), the electrical voltage used is preferably in the form of a DC voltage within a range of between 0 V and 20 V, whereby preferably, a voltage window or a ramp voltage from 2 V to higher voltages (e.g. 20 V) can be employed. In the case of metals or metal layers located on semiconductors, the voltage may amount to up to approximately 100 V in dependence upon the layer thickness of the nitride or oxynitride layer being formed, or upon any layers pre-existing on the metal such as an e.g. metal oxide layer. The substrate or the semiconductor or the metal surface thereby forms an anode with respect to at least one electrode. The at least one electrode, which forms a cathode, may comprise one of the elements silicon, platinum or graphite or be a mixture or an alloy of the aforementioned materials.

In a further embodiment of the invention, an alternating voltage may be applied or an alternating voltage component metal surface (the substrate) and at least one electrode and/or between the cathode and the second electrode. This serves, in particular, for preventing polarization effects or the deposition of unwanted substances onto a semiconductor substrate and/or the electrodes.

In a further embodiment, the nitrogenous liquid comprises nitrogen and/or hydrogen and/or deuterium in the form of dissolved gases or as components of dissolved gases.

The embodiments of the invention mentioned hereinabove are illustrated in more detail hereinafter with the aid of some exemplary embodiments.

In a first example for the production of a nitride layer on a silicon surface, this surface is first cleaned in known manner in order to remove any e.g. “native oxide”. This is effected by means of the e.g. “DHF dip” process wherein the Si wafer is dipped for e.g. approximately 0.5 min up to approximately 3 min into a 1/100 diluted e.g. 40% aqueous solution of HF (HF 40%+H₂O=1:100). In a next step, an anodic nitriding process takes place in pure liquid ammonia at approximately −50° C., whereby an electrical voltage is applied between the semiconductor substrate, the Si wafer, and an electrode made of e.g. platinum, silicon or graphite which serves as the cathode. The voltage-time curve selected is e.g. in the form of a ramp from 0 V to 10 V lasting for 30 s, whereby the voltage preferably rises in an approximately linear manner over this time period. Other voltage-time profiles deviating from such linearity are not excluded and may likewise be advantageous for exerting an influence on the e.g. polarization effects or the morphology of the layer. Silicon nitride layers of less than 5 nm can be produced on an e.g. hydrogen-passivated Si surface by means of this process in dependence on the profile of the voltage-time curve that is used.

In a second example for the production of a silicon nitride layer, the surface cleaning of the Si wafer takes place as in the first example. Afterwards, an anodic nitriding process likewise takes place in liquid ammonia at approximately −50° C., whereby about 1 g/l (gram/litre) of NH₄F is added to the liquid ammonia. A DC voltage of 6 V is applied for approximately 1 min between the Si wafer acting as an anode and a platinum electrode acting as a cathode (this electrode could also be made from silicon or graphite or comprise these elements). A thin silicon nitride layer is thereby formed and this is then brought up to the desired thickness and/or provided with the desired electrical properties in a further thermal process. The further thermal process, wherein a further growth of the silicon nitride takes place, is an e.g. RTP step wherein the wafer is exposed to a 10% NH₃ atmosphere for 30 s at 900° C. whereby argon is preferably used as a diluting gas.

As an alternative to or in addition to the thermal process in the second example, a “post nitriding annealing” process can be effected for improving the electrical properties (the layered structure) whereby the wafer is exposed to a processing atmosphere of hydrogen-rich water vapour for approximately 30 s at about 850° C. in an RTP step such as is used for e.g. hydrogen-rich wet oxidation processes.

In a third example, the surface passivating process for a silicon surface is effected with NHₓ. For this purpose, the Si wafer is cleaned as in the first example whereby the DHF step lasts for about 3 minutes in order to completely remove any “native oxide”. Afterwards, the wafer is dipped into liquid ammonia e.g. at −50° C. or is dipped into liquid ammonia having dissolved ammonium fluoride (NH₄F or NH₄F.H₂O) or choline for approximately 3 minutes, whereby approximately between 0.1 g/l and 10 g/l, preferably 1 g/l, of these substances are in the solution. The silicon surface is passivated in this step by means of an NHₓ passivating process by adsorption of preferably NH₂ molecules thereby preventing oxidation. This passivating process is preferably effected, but not necessarily, without an anodic treatment of the Si wafer i.e. without applying an electrical voltage between the wafer and the nitrogenous liquid. Alternatively or additionally, an anodic nitriding process such as that in the first example can be effected for passivating purposes, whereby a voltage having an appropriate voltage-time curve is applied between the Si wafer and a cathode. Hereby, preferably pure liquid ammonia is supplied to the wafer i.e. ammonia without further additional substances or additives.

In a fourth example, a metal coated silicon disc (e.g. an Si wafer), which is completely coated with e.g. titanium or tantalum on at least one side thereof, is dipped into liquid ammonia without pre-treatment. The subsequently applied voltage-time curve for the electrical voltage between the metal coated surface and the electrode is selected in such a way that the electrical voltage goes through an e.g. voltage ramp of from 0 V to approximately 20 V. Here, the silicon disc is connected as an anode.

The invention is not limited to the embodiments and examples specified above, and in particular, the present invention also covers those embodiments which arise from interchanging and/or combining the individual features of the different embodiments and examples. As a further important advantage of the process specified above, one may mention the low treatment temperature whereby the thermal load (thermal budget) on the semiconductor substrate is substantially reduced compared with other processes.

1-16. (canceled)

17. A process for detaching an oxygen-containing and/or nitrogenous layer on a semiconductor or metal surface, comprising;
contacting at least a part of the surface with a water-free nitrogenous liquid which comprises a fluorine-containing substance; and
separating the surface from the liquid.

18. A process on accordance with claim 17, characterized by the application of an electrical voltage between the surface, the liquid and an electrode according to a given voltage-time curve.

19. A process in accordance with claim 17, characterized in that the nitrogenous liquid consists of nitrogen and hydrogen.

20. A process in accordance with claim 17, characterized in that the nitrogenous liquid comprises NH₃, N₂H₄, N₂H₄.xH₂O or mixtures of these compounds.

21. A process in accordance with claim 17, characterized in that the nitrogenous liquid is free from dissolved or molecularly bound oxygen, free from water or free from both.

22. A process in accordance with claim 17, characterized in that the surface is part of a semiconductor substrate which essentially comprises silicon.

23. A process in accordance with claim 17, characterized in that, apart from nitrogen, the nitrogenous liquid only contains the elements hydrogen, oxygen, fluorine or carbon or combinations and/or compounds of these elements or their isotopes.

24. A process in accordance with claim 17, characterized in that the surface comprises structures.

25. A process in accordance with claim 17, characterized in that any oxygen-containing and/or nitrogenous compounds are at least partially removed from the surface prior to contacting the surface with the nitrogenous liquid.

26. A process in accordance with claim 25, characterized in that the oxygen-containing compounds comprises SiOₓ or SiO₂.

27. A process in accordance with claim 18, characterized in that the electrical voltage comprises a DC voltage component or a time-voltage profile of between 0 V and 20 V, and that the metal or semiconductor surface forms an anode with respect to at least one electrode.

28. A process in accordance with claim 17, characterized in that the surface is subjected to at least a lithographic, a thermal, a plasma-chemical treatment step, or a combination of the above steps after the separation step.

29. A process in accordance with claim 18, characterized in that the electrical voltage between the surface and at least one electrode comprises an alternating voltage.

30. A process in accordance with claim 17, characterized in that any oxygen-containing layer is detached from the surface in situ by the nitrogenous liquid.

31. A process in accordance with claim 30, characterized in that the nitrogenous liquid comprises HF, NH₄F or mixtures thereof.

32. A semiconductor substrate treated in accordance with claim 17.
